(19) United States
(12) Patent Application Publication
(10) Pub. No.: US 2013/0163329 A1
(43) Pub. Date: Jun. 27, 2013

(54) MEMORY SYSTEM

(71) Applicant: Naoya TOKIWA, Kanagawa (JP)

(72) Inventor: Naoya TOKIWA, Kanagawa (JP)

(21) Appl. No.: 13/724,898

(22) Filed: Dec. 21, 2012

(30) Foreign Application Priority Data
Dec. 22, 2011 (JP) 2011-281297

(51) Int. Cl. G11C 16/10; G11C 16/26

(52) U.S. Cl. CPC G11C 16/10; G11C 16/26
USPC 365/185.03

(57) ABSTRACT

Provided is a non-volatile semiconductor storage device according to one embodiment including: a memory cell array where memory cells capable of storing data of three or more levels are arrayed; a flag cell which is provided in an access prevention area where external access to the memory cell array is prevented; a flag data generating unit which generates flag data which is to be written in the flag cell based on a written state of the memory cell array; and an access prevention cancelling unit which permits external reading of the flag data based on an externally applied command.

### CROSS-REFERENCE TO RELATED APPLICATIONS

This application is based upon and claims the benefit of priority from Japanese Patent Application No. 2011-281297, filed on Dec. 22, 2011; the entire contents of which are incorporated herein by reference.

### FIELD

Embodiments described herein generally relates to a memory system.

### BACKGROUND

As large-capacity non-volatile memory, NAND-type flash memory has been widely known. With respect to the NAND-type flash memory, in the case where a multi-levelled technique is employed in order to implement a large capacity, read time is increased.

### BRIEF DESCRIPTION OF THE DRAWINGS

FIG. 1 is a block diagram illustrating a schematic configuration of a memory system including a non-volatile semiconductor storage device and a controller according to a first embodiment;

FIG. 2 is a circuit diagram illustrating a schematic configuration of blocks of the non-volatile semiconductor storage device illustrated in FIG. 1;

FIG. 3 is a diagram illustrating an example of a flag data adding method of the non-volatile semiconductor storage device illustrated in FIG. 1;

FIG. 4 is a diagram illustrating another example of the flag data adding method of the non-volatile semiconductor storage device illustrated in FIG. 1;

FIG. 5 is a block diagram illustrating a schematic configuration of a non-volatile semiconductor storage device according to a second embodiment;

FIG. 6 is a perspective diagram illustrating a schematic configuration of a memory cell array of the non-volatile semiconductor storage device illustrated in FIG. 5;

FIG. 7 is an enlarged cross-sectional diagram illustrating a portion E of FIG. 6;

FIG. 8 is a plan diagram illustrating a planar shape of word lines WL0 to WL7 illustrated in FIG. 6;

FIG. 9A is a cross-sectional diagram illustrating a schematic configuration of a peripheral circuit area of the non-volatile semiconductor storage device illustrated in FIG. 5, FIG. 9B is a cross-sectional diagram illustrating a schematic configuration of a word line lead-out portion of the non-volatile semiconductor storage device illustrated in FIG. 5, FIG. 9C is a cross-sectional diagram illustrating a schematic configuration cut off along line A-A of FIG. 6, and FIG. 9D is a cross-sectional diagram illustrating a schematic configuration cut off along line B-B of FIG. 6;

FIG. 10 is a diagram illustrating a configuration of a circuit corresponding to two strings of the memory cell array illustrated in FIG. 6;

FIG. 11A is a diagram illustrating a relationship between a threshold level distribution and flag data of a memory cell in an erased state, FIG. 11B is a diagram illustrating a relationship between a threshold level distribution and flag data of a memory cell in an initial state, FIG. 11C is a diagram illustrating a relationship between a threshold level distribution and flag data of a memory cell in a two-levels written state, and FIG. 11D is a diagram illustrating a relationship between a threshold level distribution and flag data of a memory cell in a four-levels written state;

FIG. 12 is a flowchart illustrating an example of an LSB data reading method of a non-volatile semiconductor storage device according to a third embodiment;

FIG. 13 is a flowchart illustrating another example of an LSB data reading method of the non-volatile semiconductor storage device according to the third embodiment;

FIG. 14 is a flowchart illustrating an example of an MSB data reading method of the non-volatile semiconductor storage device according to the third embodiment;

FIG. 15 is a flowchart illustrating another example of an MSB data reading method of the non-volatile semiconductor storage device according to the third embodiment; and

FIG. 16 is a flowchart illustrating an initialization process of a non-volatile semiconductor storage device according to a fourth embodiment.

### DETAILED DESCRIPTION

According to one embodiment, a non-volatile semiconductor storage device includes a memory cell configured to be capable of storing data of three or more levels, a flag cell configured to be capable of storing a first data, a first unit electrically connected to the flag cell, the first unit configured to generate the first data based on a threshold level of the memory cell, and an second unit configured to generate a second data in order to allow access to the flag cell by external data.

Hereinafter, the non-volatile semiconductor storage device according to the embodiments will be described with reference to the drawings. Components with substantially the same functionalities and configurations will be referred to with the same reference number and duplicate descriptions will be made only when required. Note that figures are schematic and the relationship between the thickness and the plane dimension of a film and the ratios of the thickness of one layer to another may differ from actual values. Therefore, it should be noted that a specific thickness and dimension should be determined in accordance with the following description. Moreover, it is natural that different figures may contain a component different in dimension and/or ratio.

### First Embodiment

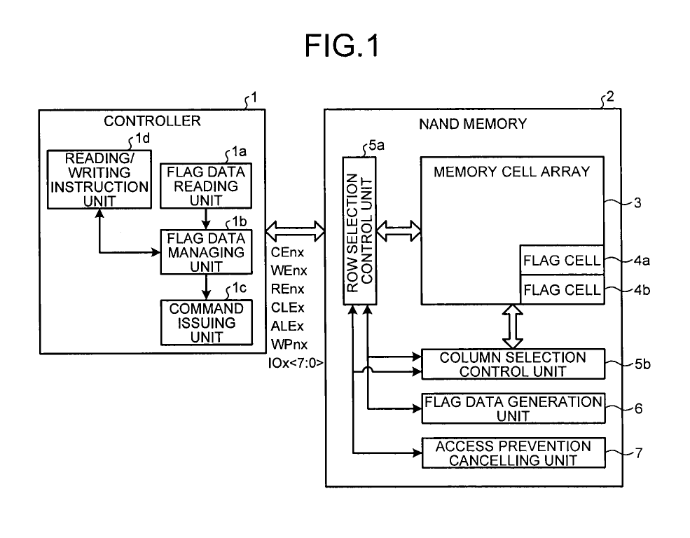

FIG. 1 is a block diagram illustrating a schematic configuration of a memory system including a non-volatile semiconductor storage device and a controller according to a first embodiment.

In FIG. 1, the non-volatile semiconductor storage device includes a NAND memory 2. In addition, the NAND memory 2 is connected to a controller 1 which performs drive control. In addition, as the drive control of the NAND memory 2, there are, for example, read/write control, block selection, error correction, wear leveling, and the like of the NAND memory 2.

The NAND memory 2 includes a memory cell array 3, a row selection control unit 5a, a column selection control unit 5b, a flag data generating unit (a first unit) 6, and an access prevention cancelling unit (a second unit) 7. In the memory cell array 3, memory cells capable of storing three or more levels are arrayed in row and column directions in a matrix shape, and flag cells 4a and 4b are provided in an access prevention area preventing external access to the memory cell array 3. Herein, word lines performing row selection for the memory cells and bit lines performing column selection for the memory cells are provided in the memory cell array 3. In addition, the flag cells 4a and 4b share word lines with the memory cells and have dedicated bit lines with respect to the memory cells. In addition, in the description hereinafter, the memory cell is configured to be capable of storing four-level data.

Herein, the flag cells 4a and 4b can be disposed, for example, at addresses exceeding the final address of each page. In addition, the flag cell 4a can retain the first flag data distinguishing the erased state and the initial state of the memory cell array 3. The flag cell 4b can retain the second flag data distinguishing the written state of only the lower bit of the memory cell array 3 and the written states of the lower and upper bits of the memory cell array 3. In addition, in a memory cell capable of storing four levels, the lower bit corresponds to the LSB (Least Significant Bit) and the upper bit corresponds to the MSB (Most Significant Bit).

In the reading and writing of the memory cells of the memory cell array 3, the row selection control unit 5a can perform row selection and control of an applied voltage for each row. In the reading and writing of the memory cells of the memory cell array 3, the column selection control unit 5b can perform column selection and control of an applied voltage for each column. The flag data generating unit 6 can generate the first and second flag data which are to be written in the flag cells 4a and 4b based on the written state of the memory cell array 3. The access prevention cancelling unit 7 permits external access to the flag cells 4a and 4b based on an externally applied command, so that the first and second flag data are allowed to be externally read from the flag cells 4a and 4b.

The controller 1 includes a flag data reading unit (a first unit) 1a, a flag data managing unit (a second unit) 1b, a command issuing unit (a third unit) 1c, and a reading/writing instruction unit (a forth unit) 1d. The flag data reading unit 1a can read the first and second flag data from the flag cells 4a and 4b of the NAND memory 2. The flag data managing unit 1b can manage the first and second flag data which are to be stored in the flag cells 4a and 4b, respectively. The command issuing unit 1c can issue a command for reading data from the NAND memory 2 based on the first or second flag data which are managed by the flag data managing unit 1b. The reading/writing instruction unit 1d can instruct the NAND memory 2 to perform reading and writing.

Herein, in the case where the second flag data which are managed by the flag data managing unit 1b indicate written states of lower and upper bits, the command issuing unit 1c can issue a first command. In addition, in the case where the second flag data which are managed by the flag data managing unit 1b indicate a written state of only the lower bit, the command issuing unit 1c can issue a second command.

Next, in the case where data are to be erased in the NAND memory 2, the controller 1 issues an erase command to the NAND memory 2. Next, in the NAND memory 2, data stored in the memory cell array 3 are erased in units of a block. In the erasing operation, the threshold level distributions of all the memory cells of each block can be set to be negative.

At this time, if a written memory cell adjacent to the erased memory cell exists, since the threshold level distribution of the written memory cell becomes positive, interference may occur between the adjacent memory cells.

Accordingly, if a memory cell is erased, the memory cell is transitioned from the erased state to the initial state having a positive threshold level distribution. In addition, the threshold level distribution of the memory cell in the initial state can be set to be higher than the threshold level distribution of the memory cell in the erased state in terms of voltage.

Herein, if the memory cell is set to the erased state, the first flag data is set to “0” in the entire erasing units. The second flag data is also set to “0”. In addition, if the memory cell is set to the initial state or the written state, the flag data generating unit 6 can set the first flag data to “1” in units of a page. Next, if the first flag data are set, the first flag data are written in the flag cell 4a through the row selection control unit 5a and the column selection control unit 5b.

In addition, in the case where the LSB is to be written in the NAND memory 2, the controller 1 issues an LSB write command to the NAND memory 2. Next, in the NAND memory 2, LSB is written in the address designated by the controller 1. In the LSB writing operation, one threshold level distribution in the initial state is divided into two threshold level distributions, so that a two-level state can be acquired.

In addition, in the case where the MSB is to be written in the NAND memory 2, the controller 1 issues an MSB write command to the NAND memory 2. Next, in the NAND memory 2, MSB is written in the address designated by the controller 1. In the MSB writing operation, two threshold level distributions in the MSB written state are divided into four threshold level distributions, so that a four-level state can be acquired.

Herein, if the memory cell is set to the erased state, the initial state, or the LSB written state, the flag data generating unit 6 does not update the content of the second flag data, that is, retains “0” of the erased state. In addition, if the memory cell is set to the MSB written state, the flag data generating unit 6 can set the second flag data to “1” in units of a page. Next, if the second flag data is set, the second flag data are written in the flag cell 4b through the row selection control unit 5a and the column selection control unit 5b.

In addition, the flag data managing unit 1b can manage the first and second flag data which are to be written in the flag cells 4a and 4b according to the written state of the NAND memory 2. In addition, the flag data managing unit 1b can issue an access prevention cancelling command for cancelling prevention of access to the flag cells 4a and 4b to the NAND memory 2. Next, in the NAND memory 2, if the access prevention cancelling command is issued, prevention of access to the flag cells 4a and 4b is cancelled by the access prevention cancelling unit 7. Next, the first or second flag data which is stored in the flag cells 4a and 4b, respectively, are read through the row selection control unit 5a and the column selection control unit 5b and are transmitted to the controller 1. In addition, even in the case where the first and second flag data which are managed by the flag data managing unit 1b are lost due to power off or the like of the controller 1, the flag data managing unit 1b can check the first and second flag data which are written in the flag cells 4a and 4b, respectively.

In addition, in the case where the LSB reading is performed in the NAND memory 2, the reading/writing instruction unit 1d checks the second flag data which are managed by the flag data managing unit 1b. Next, in the case where the second flag data is “1”, the controller 1 issues a first read command for the LSB to the NAND memory 2. Next, in the NAND memory 2, the LSB corresponding to four levels is read from the address designated by the controller 1. On the other hand, in the case where the second flag data is “0”, the controller 1 issues a second read command for the LSB to the NAND memory 2. Next, in the NAND memory 2, the LSB corresponding to two levels is read from the address designated by the controller 1.

In addition, in the case where the MSB reading is performed in the NAND memory 2, the reading/writing instruction unit 1d checks the second flag data which are managed by the flag data managing unit 1b. Next, in the case where the second flag data is “1”, the controller 1 issues the first read command for the MSB to the NAND memory 2. Next, in the NAND memory 2, the MSB corresponding to four levels is read from the address designated by the controller 1. On the other hand, in the case where the second flag data are “0”, the controller 1 issues the second read command for the MSB to the NAND memory 2. Next, in the NAND memory 2, reading data of all of reading data in a page is set to “1” based on the address designated by the controller 1.

Herein, in the controller 1 side, the first and second read commands are properly used according to the level of the second flag data, so that in the NAND memory 2 side, the reading times for the flag cell 4a can be reduced. Accordingly, it is possible to reduce a read time.

In addition, the first and second flag data which are to be stored in the flag cells 4a and 4b are allowed to be read in the controller 1 side, so that even in the case where the first and second flag data which are managed by the flag data managing unit 1b are lost, the first and second flag data which are to be stored in the flag cells 4a and 4b can be checked in the controller 1 side.

In addition, in the NAND memory 2, for example, in the case where the NAND memory 2 is powered on, the first flag data which is written in the flag cell 4a is read through the row selection control unit 5a and the column selection control unit 5b. In addition, in the case where the first flag data is “0”, the initialization process of transitioning the memory cell array from the erased state into the initial state is performed in units of a page. At this time, the controller 1 instructs reading of the first flag data; data are output by the instruction of the controller 1; and the initialization process is performed in units of a page by the instruction of the controller 1.

Therefore, even in the case where the initialization process of transitioning the memory cell array from the erased state into the initial state is stopped due to the power off or the like of the NAND memory 2, the initialization process can be restarted after the NAND memory 2 is powered on, so that the stability of the data storage can be improved.

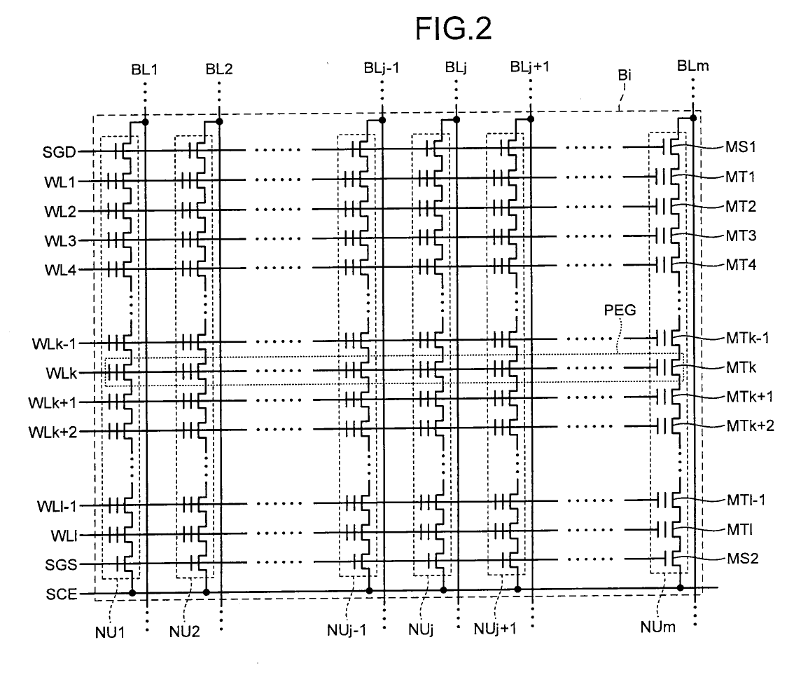

FIG. 2 is a circuit diagram illustrating a schematic configuration of blocks of the non-volatile semiconductor storage device illustrated in FIG. 1.

In FIG. 2, the memory cell array 3 illustrated in FIG. 1 is divided into n (n is a positive integer) blocks B1 to Bn. In addition, the block Bi (i is an integer of 1≦i≦n) includes 1 (1 is a positive integer) word lines WL1 to WL1, the select gate lines SGD and SGS, and the source line SCE. In addition, m (m is a positive integer) bit lines BL1 to BLm are commonly provided in the blocks B1 to Bn.

In addition, the block Bi includes m NAND cell units NU1 to NUm, and the NAND cell units NU1 to NUm are connected to the bit lines BL1 to BLm, respectively.

Herein, each of the NAND cell units NU1 to NUm includes the cell transistors MT1 to MT1 and the select transistors MS1 and MS2. In addition, one memory cell of the memory cell array 3 can be configured with one cell transistor MTk (k is an integer of 1≦k≦1). In addition, each of the cell transistors MT1 to MT1 can include a charge storage layer which stores electric charges. In addition, a NAND string is configured by connecting the cell transistors MT1 to MT1 in series, and the NAND cell unit NUj (j is an integer of 1≦j≦m) is configured by connecting the select transistors MS1 and MS2 to the both ends of the NAND string.

In addition, in the NAND cell units NU1 to NUm, the control gate electrodes of the cell transistors MT1 to MT1 are connected to the word lines WL1 to WL1, respectively. In addition, in the NAND cell unit NUj, the one end of the NAND string configured with the cell transistors MT1 to MT1 is connected to the bit line BLj through the select transistor MS1; and the other end of the NAND string is connected to the source line SCE through the select transistor MS2.

In addition, in the NAND cell units NU1 to NUm, a page PEG can be configured in the m memory cells, each of which is configured with the cell transistor MTk connected to the word line WLk.

Next, in the writing operation, a write voltage is applied to the selected word line WLk of the block Bi, and 0 V is applied to the selected bit line BLj of the block Bi. In addition, a voltage (for example, 10 V) which is sufficient to turn on the cell transistors MT1 to MTk−1 is applied to the non-selected word lines WL1 to WLk−1 which are closer to the bit line BLj than the selected word line WLk. A voltage (for example, 0 V) which is sufficient to turn off the cell transistors MTk+1 to MT1 is applied to the non-selected word lines WLk+1 to WL1 which are closer to the source line SCE than the selected word line WLk.

In addition, a voltage which is sufficient to turn on the select transistor MS1 is applied to the select gate line SGD; and a voltage which is sufficient to turn off the select transistor MS2 is applied to the select gate line SGS.

Therefore, the voltage of 0 V applied to the bit line BLj is transferred through the cell transistors MT1 to MTk-1 of the NAND cell unit NUj to the drain of the cell transistor MTk, and a high voltage is applied to the control gate electrode of the selected cell, so that the potential of the charge storage area of the selected cell is increased. Accordingly, due to the tunneling effect, electrons from the drain of the selected cell are injected into the charge storage area, and thus, the threshold level of the cell transistor MTk is increased, so that the writing operation of the selected cell is performed.

If the writing operation of the selected cell of the block Bi is performed, a write verifying operation is performed in order to check whether or not the threshold level reaches a target threshold level. At this time, a verify voltage is applied to the selected word line WLk of the block Bi, and a voltage (for example, 4.5 V) which is sufficient to turn on the cell transistors MT1 to MTk−1 and MTk+1 to MT1 is applied to the non-selected word lines WL1 to WLk−1 and WLk+1 to WL1. In addition, a voltage (for example, 4.5 V) which is sufficient to turn on the select transistors MS1 and MS2 is applied to the select gate lines SGD and SGS. In addition, a precharge voltage is applied to the bit line BLj, and a voltage necessary for reading is applied to the source line SCE.

At this time, if the threshold level of the selected cell reaches the target threshold level, the electric charges charged in the bit line BLj are not discharged through the NAND cell unit NUj, so that the potential of the bit line BLj holds a precharge level. On the other hand, if the threshold level of the selected cell does not reach the target threshold level, since the electric charges charged in the bit line BLj are discharged through the NAND cell unit NUj, so that the potential of the bit line BLj becomes a low level.

Next, the verify check is performed according to whether or not the potential of the bit line BLj is in the low or high level. In addition, if the threshold level of the selected cell reaches the target threshold level, the writing process is ended.

On the other hand, if the threshold level of the selected cell does not reach the target threshold level, the write voltage VPGM is increased by a step-up voltage ΔVPGM. Next, until the verify check is passed, the step-up voltage ΔVPGM is increased, and until the threshold level of the selected cell reaches the target threshold level, the write voltage VPGM is repetitively applied, so that the writing of the memory cell is performed.

Herein, writing of four-level information in a memory cell is performed by allowing electric charges of which amount corresponds to the four-level information to be injected into the charge storage layer of each memory cell. In addition, since the threshold level of the cell transistor MTk is changed according to the amount of electric charges of the charge storage layer, a predetermined voltage identifying four levels is applied to the cell transistor MTk, and it can be read which one of the four levels is written based on the operation state at this time.

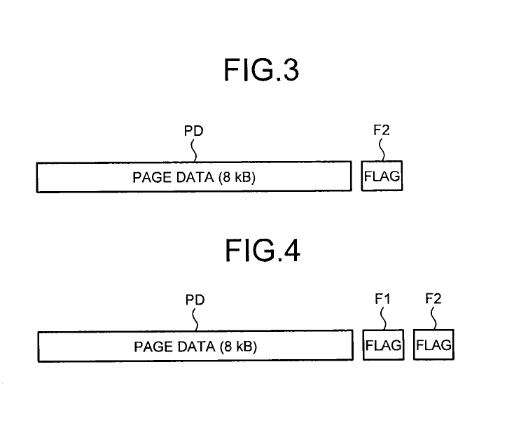

FIG. 3 is a diagram illustrating an example of a flag data adding method of the non-volatile semiconductor storage device illustrated in FIG. 1.

In FIG. 3, for example, a capacity of the page data PD corresponding to one page can be set to 8 kB. In addition, in the case where the second flag data F2 is added in units of a page, the second flag data F2 can be allocated to the address next to the final address of the page data PD.

FIG. 4 is a diagram illustrating another example of the flag data adding method of the non-volatile semiconductor storage device illustrated in FIG. 1.

In FIG. 4, for example, a capacity of the page data PD corresponding to one page can be set to 8 kB. In addition, in the case where the first flag data F1 and the second flag data F2 are added in units of a page, the first flag data F1 can be allocated to the address next to the final address of the page data PD, and the second flag data F2 can be allocated to the address next to the aforementioned address.

### Second Embodiment

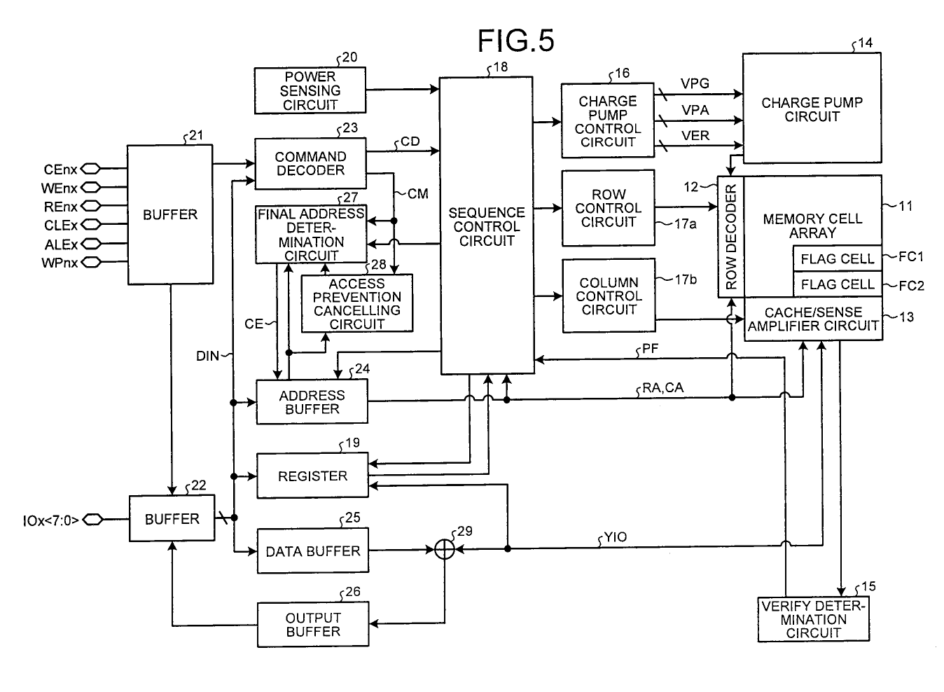

FIG. 5 is a block diagram illustrating a schematic configuration of a non-volatile semiconductor storage device according to a second embodiment.

In FIG. 5, the non-volatile semiconductor storage device includes a memory cell array 11, a row decoder 12, a cache/sense amplifier circuit 13, a charge pump circuit 14, a verify determination circuit 15, a charge pump control circuit 16, a row control circuit 17a, a column control circuit 17b, a sequence control circuit 18, a register 19, a power sensing circuit 20, buffers 21 and 22, a command decoder 23, an address buffer 24, a data buffer 25, an output buffer 26, a final address determination circuit 27, an access prevention cancelling circuit 28, and a multiplexer 29. In the memory cell array 11, memory cells capable of storing three or more levels are arrayed, and flag cells FC1 and FC2 are provided in an access prevention area preventing external access to the memory cell array 11. In addition, when a command permitting access to the access prevention area is applied, or when the access is performed by an internal operation, the access prevention area can be accessed. In addition, the register 19, the buffer 22, the command decoder 23, the address buffer 24, and the data buffer 25 are connected via a bus DIN. In addition, the cache/sense amplifier circuit 13, the register 19, and the multiplexer 29 are connected via a bus YIO. In addition, the data buffer 25 and the output buffer 26 are connected to the bus YIO through the multiplexer 29.

Herein, the flag cells FC1 and FC2 can be disposed, for example, at addresses exceeding the final address of each page. In addition, the flag cell FC1 can retain the first flag data distinguishing the erased state and the initial state of the memory cell array 11. The flag cell FC2 can retain the second flag data distinguishing the written state of only the lower bit of the memory cell array 11 and the written states of the lower and upper bits of the memory cell array 11.

A chip enable signal CEnx, a write enable signal WEnx, a read enable signal REnx, a command latch enable signal CLEx, an address latch enable signal ALEx, and a write protect signal WPnx are input from an external control device to the buffer 21. In addition, commands, addresses, and writing data are input from the external control device through an input/output port IOx<7:0> to the buffer 22, and reading data is output from the buffer 22 through the input/output port IOx<7:0> to the external control device. In addition, as the external control device, for example, the controller 1 illustrated in FIG. 1 can be used.

Next, if the command latch enable signal CLEx is activated, the buffer 22 transmits a command to the command decoder 23 in response to an output of the buffer 21. In addition, if the address latch enable signal ALEx is activated, the buffer 22 transmits an address to the address buffer 24 in response to an output of the buffer 21. In addition, if the write enable signal WEnx is activated, the buffer 22 transmits writing data to the data buffer 25 in response to an output of the buffer 21. In addition, if the read enable signal REnx is activated, the buffer 22 acquires reading data from the output buffer 26 and transmits the reading data to the input/output port IOx<7:0> in response to an output of the buffer 21.

Next, the command decoder 23 analyzes the command and determines starting of other necessary operations in addition to writing, reading, or erasing or internal operation states if necessary. Next, an instruction signal CD instructing the starting of the operations is notified to the sequence control circuit 18.

In addition, the address buffer 24 retains write, erase, or read address input through the buffer 22. The address buffer 24 outputs a row address RA to the row decoder 12 and outputs a column address CA to the cache/sense amplifier circuit 13 according to control of the sequence control circuit 18. In addition, if necessary, the address buffer 24 may constitute a counter circuit, or the address buffer 24 may be embedded with an address comparison circuit.

The data buffer 25 temporarily stores writing data input through the buffer 22 and transmits the writing data or the erasing data through the bus YIO to the cache/sense amplifier circuit 13.

The output buffer 26 temporarily stores read data read through the cache/sense amplifier circuit 13 and transmits the read data to the buffer 22.

The register 19 can temporarily store externally-input data or data stored in the memory cell array 11.

The row control circuit 17a controls operation timing of the row decoder 12 according to instruction of the sequence control circuit 18. The column control circuit 17b controls operation timing of the cache/sense amplifier circuit 13 according to instruction of the sequence control circuit 18.

The charge pump control circuit 16 designates voltages necessary for writing, reading, and erasing according to instruction from the sequence control circuit 18 and outputs voltage designation signals VPG, VPA, and VER to the charge pump circuit 14.

The charge pump circuit 14 generates voltages necessary for writing, reading, and erasing based on the voltage designation signals VPG, VPA, and VER and outputs the voltages to the row decoder 12 and the cache/sense amplifier circuit 13.

The cache/sense amplifier circuit 13 at least one page or more of a plurality of resisters (cache) for temporarily storing read data or write data. Next, by sensing a potential of a bit line connected to a selected cell, the read data is determined, and the read data is output to the output buffer 26.

The row decoder 12 applies voltages necessary for writing, reading, or erasing to the word line of the selected row, so that writing, reading, or erasing of the memory cell array 11 is allowed to be performed.

The verify determination circuit 15 determines whether or not the writing are to be completed by determining the reading data read from the selected cell are coincident with the writing data mainly during the writing period. Next, the result of determination of writing completion is notified as a pass signal PF to the sequence control circuit 18.

The sequence control circuit 18 controls the reading operation, the writing operation, the erasing operation, and other embedded test operations of the memory cell according to the instruction signal CD, the pass signal PF, or the like. The control of the reading operation, the writing operation, and the erasing operation of the memory cell is performed by allowing the charge pump control circuit 16, the row control circuit 17a, and the column control circuit 17b to control the row decoder 12, the cache/sense amplifier circuit 13, and the charge pump circuit 14.

The final address determination circuit 27 always monitors a state of a column address counter which is disposed in the address buffer 24 and, in the case where the column address counter indicates an area rather than the predetermined area, the control is performed so that the predetermined area is not exceeded. For example, in the case where the column address is started from the address 0 and the length of a page is 8 kB, the final address is the address 8191.

Therefore, in the case where reading or writing from the address 0 to the address 8191 is to be performed, the final address determination circuit 27 does not present an access prevention signal CE to the address buffer 24 but permits reading or writing at any address.

On the other hand, in the case where access is to be performed beyond the area of 8 kB, for example, if the address 8192 is externally applied as the reading start address or the writing start address, the access prevention signal CE is activated, so that it is controlled so that reading or writing at the address may not be performed. In addition, in the case where the read enable signal REnx is applied exceeding 8192 times during the reading from the address 0, the access prevention signal CE is activated, so that it is controlled so that the reading may not be performed.

As a read preventing method, the final address data may be continuously output; it is returned to the address 0 and data may be continuously output; and a message indicating that the final address is exceeded may be notified. As a write preventing method, data applied to an area rather than the area of 8 kB may be neglected; and a specific area of 8 kB may be overwritten.

Herein, for example, in the case where the flag cells FC1 and FC2 are allocated to address 8192, in order to allow the flag cells FC1 and FC2 to be accessed, access limitation of the final address determination circuit 27 is temporarily cancelled by the instruction of the sequence control circuit 18, so that the access prevention signal CE can be temporarily in an inactivated state.

In addition, in order to allow the flag cells FC1 and FC2 to be externally accessed, the access prevention cancelling circuit 28 temporarily cancels prevention of access to the final address determination circuit 27 based on an externally applied command and allows the access prevention signal CE to be temporarily in an inactivated state.

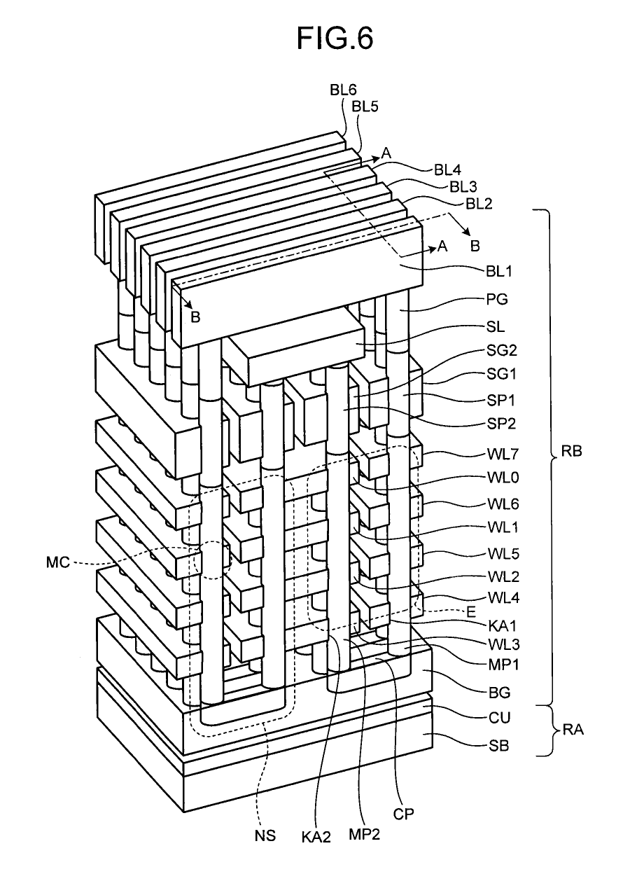

FIG. 6 is a perspective diagram illustrating a schematic configuration of a memory cell array of the non-volatile semiconductor storage device illustrated in FIG. 5. In addition, the example of FIG. 6 illustrates a method of forming a NAND string NS by connecting 8 memory cells MC in series by repetitively forming memory cells MC, where four layers are stacked, in the lower end portion.

In FIG. 6, a circuit area RA is provided on semiconductor substrate SB, and a memory area RB is provided over the circuit area RA. In addition, the substrate in which the circuit area RA is to be provided and the substrate in which the memory area RB is to be provided may be separately formed.

In addition, with respect to the semiconductor substrate SB, a circuit layer CU is formed in the circuit area RA. In addition, the row decoder 12, the cache/sense amplifier circuit 13, the charge pump circuit 14, the verify determination circuit 15, the charge pump control circuit 16, the row control circuit 17a, the column control circuit 17b, the sequence control circuit 18, the register 19, the power sensing circuit 20, the buffers 21 and 22, the command decoder 23, the address buffer 24, the data buffer 25, the output buffer 26, the final address determination circuit 27, the access prevention cancelling circuit 28, and the multiplexer 29 illustrated in FIG. 5 can be formed in the circuit layer CU. The memory cell array 11 illustrated in FIG. 5 can be formed in the memory area RB.

In addition, in the memory area RB, a back gate layer BG is formed over the circuit layer CU, and a connection layer CP is formed in the back gate layer BG. On the connection layer CP, the columnar structures MP1 and MP2 are disposed to be adjacent to each other, and the bottom ends of the columnar structures MP1 and MP2 are connected to each other through the connection layer CP. In addition, on the connection layer CP, the word lines WL3 to WL0 as four layers are sequentially stacked, and the word lines WL4 to WL7 as four layers are sequentially stacked so that the word lines WL3 to WL0 are adjacent to each other. Next, the word lines WL4 to WL7 are penetrated by the columnar structure MP1, and the word lines WL0 to WL3 are penetrated by the columnar structure MP2, so that the NAND string NS is configured.

In addition, columnar structures SP1 and SP2 are formed on the columnar structures MP1 and MP2, respectively.

A select gate electrode SG1 penetrated by the columnar structure SP1 is formed over the word line WL7 of the uppermost layer, and a select gate electrode SG2 penetrated by the columnar structure SP2 is formed over the word line WL0 of the uppermost layer.

In addition, the source line SL connected to the columnar structure SP2 is provided over the select gate electrode SG2, and, for each column, the bit lines BL1 to BL6 connected to the columnar structure SP1 through a plug PG are formed over the select gate electrode SG1. In addition, the columnar structures MP1 and MP2 can be disposed at intersections of the bit lines BL1 to BL6 and the word lines WL0 to WL7.

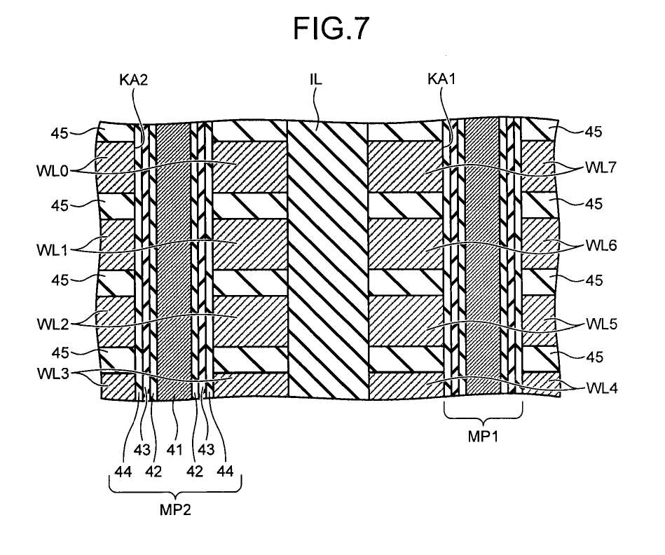

FIG. 7 is an enlarged cross-sectional diagram illustrating a portion E of FIG. 6.

In FIG. 7, an insulating material IL is buried between the word lines WL0 to WL3 and the word lines WL4 to WL7. An interlayer insulating film 45 is formed between the word lines WL0 to WL3 and between the word lines WL4 to WL7.

In addition, with respect to the word lines WL0 to WL3 and the interlayer insulating film 45, a through-hole KA2 is formed to penetrate the lines in the stacked direction; and with respect to the word lines WL4 to WL7 and the interlayer insulating film 45, a through-hole KA1 is formed to penetrate the lines in the stacked direction. The columnar structure MP1 is formed within the through-hole KA1, and the columnar structure MP2 is formed within the through-hole KA2.

A columnar semiconductor 41 is formed at the centers of the columnar structures MP1 and MP2. A tunneling insulating film 42 is formed between inner surfaces of the through-holes KA1 and KA2 and the columnar semiconductor 41; a charge trapping layer 43 is formed between inner surfaces of the through-holes KA1 and KA2 and the tunneling insulating film 42; and a block insulating film 44 is formed between inner surfaces of the through-holes KA1 and KA2 and the charge trapping layer 43. For the columnar semiconductor 41, for example, a semiconductor such as Si can be used. For the tunneling insulating film 42 and the block insulating film 44, for example, a silicon oxide film can be used. For the charge trapping layer 43, for example, a silicon nitride film or an ONO film (three-layer structure of silicon oxide film/silicon nitride film/silicon oxide film) can be used.

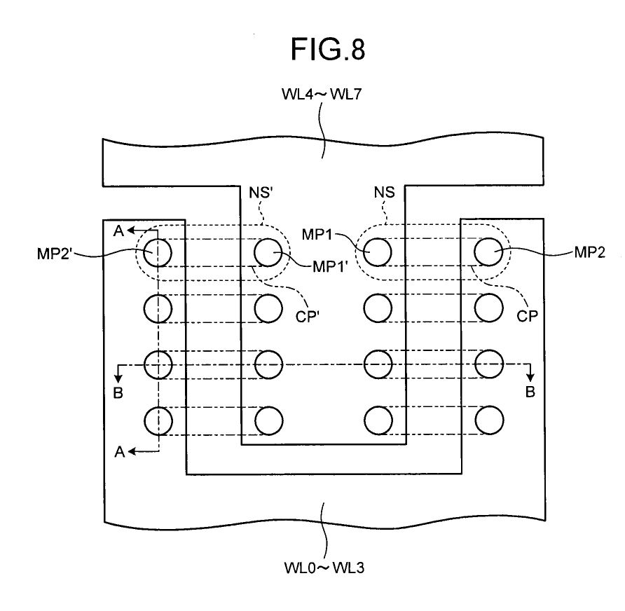

FIG. 8 is a plan diagram illustrating a planar shape of the word lines WL0 to WL7 illustrated in FIG. 6.

In FIG. 8, a NAND string NS′ is provided to be adjacent to the NAND string NS, where the columnar structures MP1 and MP2 are provided, in the column direction. In addition, columnar structures MP1′ and MP2′ are provided in the NAND string NS′, and the columnar structures MP1′ and MP2′ are connected to each other a connection layer CP′.

Herein, the columnar structures MP1 and MP1′ are disposed to be adjacent to each other in the column direction. In addition, the columnar structures MP1 and MP1′ penetrate the word lines WL4 to WL7. In addition, the columnar structures MP1 and MP1′ are connected to a BL in FIG. 6.

In addition, the columnar structures MP2 and MP2′ are disposed. In addition, the columnar structures MP2 and MP2′ penetrate the word lines WL0 to WL3. In addition, the columnar structures MP2 and MP2′ are connected to the source line SL illustrated in FIG. 6 for each column. Herein, the word lines WL0 to WL3 and the word lines WL4 to WL7 are formed in a comb-like shape so as to have a mutually nested structure.

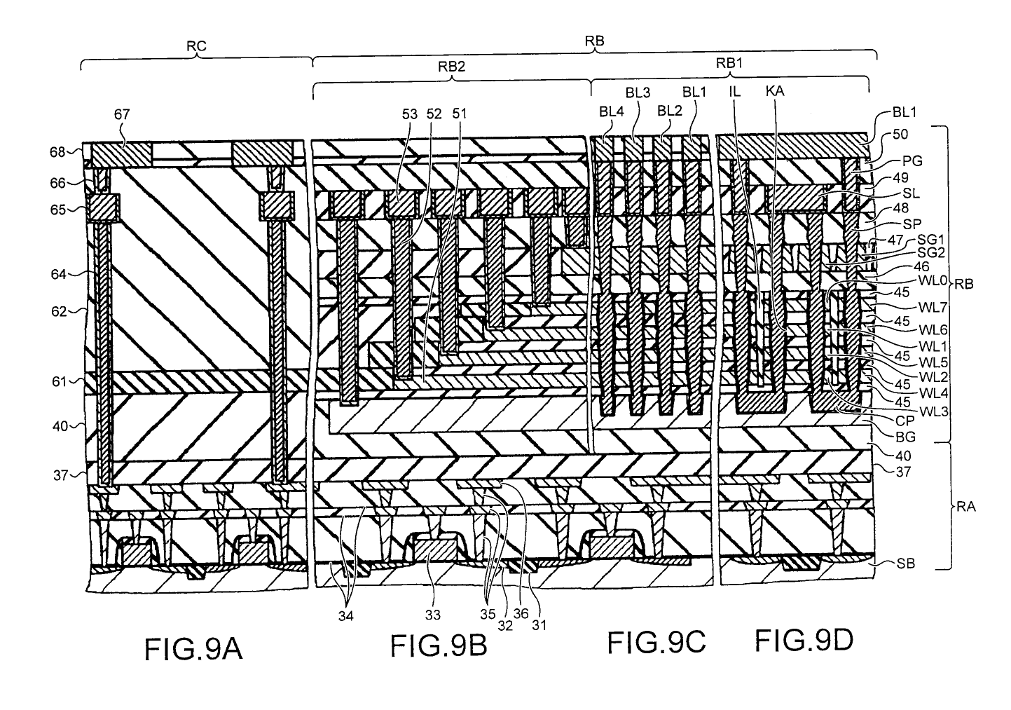

FIG. 9A is a cross-sectional diagram illustrating a schematic configuration of the peripheral circuit area of the non-volatile semiconductor storage device illustrated in FIG. 5; FIG. 9B is a cross-sectional diagram illustrating a schematic configuration of the word line lead-out portion of the non-volatile semiconductor storage device illustrated in FIG. 5; FIG. 9C is a cross-sectional diagram taken line A-A of FIG. 6; and FIG. 9D is a cross-sectional diagram taken line B-B of FIG. 6.

In FIGS. 9A to 9D, a peripheral area RC is provided in the vicinity of the memory area RB. In addition, a circuit area RA can be provided in the peripheral area RC. In addition, a memory cell area RB1 and a lead-out area RB2 are provided in the memory area RB.

In addition, in the circuit area RA of the semiconductor substrate SB, STI (shallow trench isolation) 31 is formed. In addition, a diffusion layer 32 is formed in an active area isolated by the STI 31, and a gate electrode 33 is disposed over a channel area between the diffusion layers 32, so that a transistor is formed. In addition, an interlayer insulating film 34 is formed over the semiconductor substrate SB where the transistor is formed, and a plug 35 and a wire line 36 are buried in the interlayer insulating film 34. In addition, interlayer insulating films 37 and 40 are formed over the wire line 36.

In addition, in the memory cell area RB1, a back gate layer BG is formed on the interlayer insulating film 40, and a connection layer CP is formed in the back gate layer BG. In addition, the word lines WL0 to WL3 are sequentially stacked through the interlayer insulating film 45, and the word lines WL4 to WL7 are sequentially stacked through the interlayer insulating film 45.

In addition, a select gate electrode SG2 is formed over the word line WL0 through an interlayer insulating film 46, and a select gate electrode SG1 is formed over the word line WL7 through the interlayer insulating film 46. In addition, an interlayer insulating film 47 is buried between the select gate electrodes SG1 and SG2.

In addition, the source line SL is formed over the select gate electrode SG2 through an interlayer insulating film 48, and the source line SL is buried in an interlayer insulating film 49. In addition, the bit line BL1 is formed over the select gate electrode SG1 and the source line SL through an interlayer insulating film 50.

In addition, in the lead-out area RB2, a back gate layer BG is formed over the interlayer insulating film 40. In addition, a lead-out line 51 is lead out from each of the word lines WL0 to WL7 is formed in each layer. Herein, the end portions of the lead-out lines 51 are disposed to be shifted for the layers, so that the end portions of the lead-out lines 51 of the layers are not overlapped in the up/down direction. In addition, the end portion of the lead-out lines 51 of the layers are connected to a wire line 53 through a plug 52, so that the word lines WL0 to WL7 are connected to the circuit layer CU.

In addition, in the peripheral area RC, interlayer insulating films 61, 62, and 68 are formed over the interlayer insulating film 40. In addition, plugs 64 and 66 and wire lines 65 and 67 are buried in the interlayer insulating films 37, 40, 61, 62, and 68.

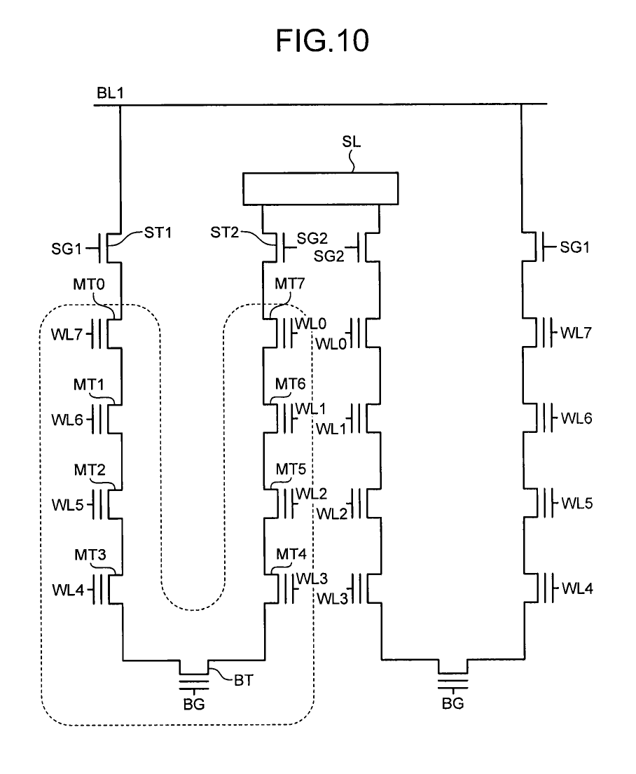

FIG. 10 is a circuit diagram illustrating a configuration of a circuit corresponding to two strings of the memory cell array illustrated in FIG. 6.

In FIG. 10, the cell transistors MT0 to MT7 are provided in the NAND string NS, and each of the cell transistors MT0 to MT7 may constitute the memory cell MC. Herein, the gates of the cell transistors MT0 to MT7 are connected to the word lines WL7 to WL0, respectively.

In addition, the cell transistors MT0 to MT3 are connected in series, and the cell transistors MT4 to MT7 are connected in series. In addition, the cell transistors MT3 and MT4 are connected to each other through a back gate transistor BT. The cell transistor MT0 is connected to the bit line BL1 through a select transistor ST1; and the cell transistor MT7 is connected to the source line SL through a select transistor ST2. The select gate electrodes SG1 and SG2 are provided in the select transistors ST1 and ST2.

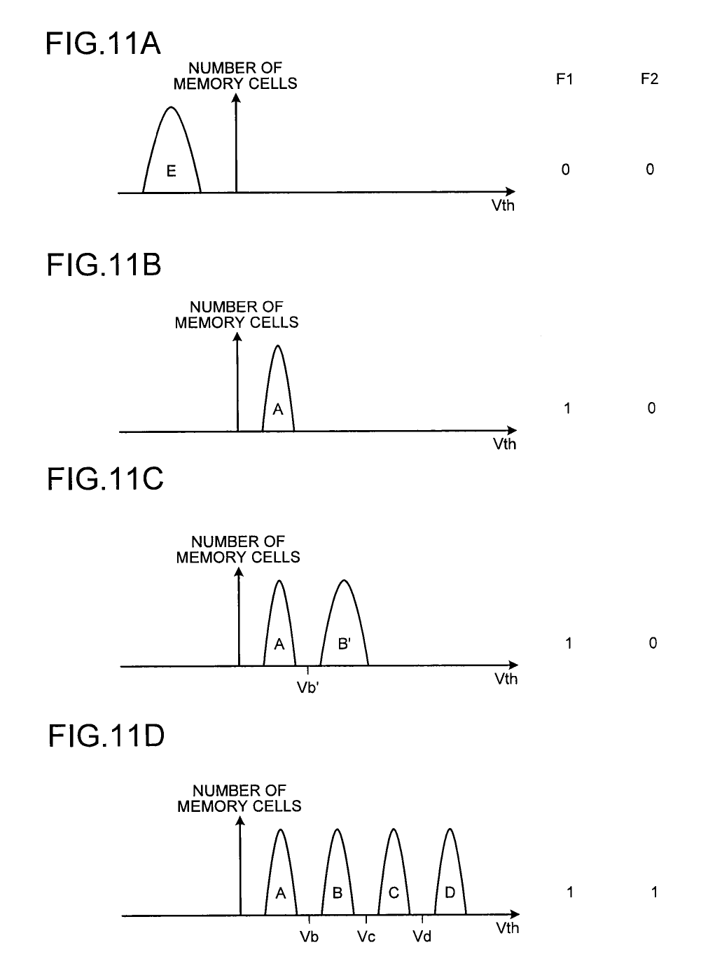

FIG. 11A is a diagram illustrating a relationship between a threshold level distribution and flag data of a memory cell in an erased state; FIG. 11B is a diagram illustrating a relationship between a threshold level distribution and flag data of a memory cell in an initial state; FIG. 11C is a diagram illustrating a relationship between a threshold level distribution and flag data of a memory cell in a two-level written state; and FIG. 11C is a diagram illustrating a relationship between a threshold level distribution and flag data of a memory cell in a four-level written state.

In FIG. 11A, in the erasing operation, threshold level distributions E of all the memory cells in the to-be-erased block are set to be negative. In addition, in FIG. 11B, in the initializing operation, one threshold level distribution A is generated with respect to all the memory cells of each block, and the threshold level distribution A is set to be positive. In addition, in FIG. 11C, in the two-levelled writing operation, two threshold level distributions A and B′ are generated with respect to the written memory cells of each block, and the threshold level distributions A and B′ are set to be positive. In addition, in FIG. 11D, in the four-levelled writing operation, four threshold level distributions A to D are generated with respect to the written memory cells of each block, and the threshold level distributions A to D are set to be positive. Herein, the threshold level distributions A to D are allowed to correspond to 2-bit data “11”, “10”, “01”, and “00”.

Herein, the threshold level distribution E is set to be negative from the upper limit to the lower limit, and the threshold level distributions A to D are set to be positive from the upper limit to the lower limit. Therefore, the threshold level distribution E does not interfere with the threshold level distributions A to D, so that the width of the threshold level distribution E can be larger than the widths of the threshold level distributions A to D. Accordingly, during the erase period, a high voltage is applied, and an accuracy of the erase verify can be decreased in comparison with the write verify, so that a time taken for the erasing can be reduced.

In the erasing operation, 0 V is applied to the word lines WL0 to WL7 for erase block, the potential of the columnar semiconductor 41 illustrated in FIG. 7 is set to an erase voltage Ve. In addition, the erase voltage Ve is set to a high voltage, for example, about 20 V. In addition, the source line SL and the select gate electrodes SG1 and SG2 of erase block can be set to voltages necessary for the erasing.

At this time, a high voltage is applied between the columnar semiconductor 41 and the word lines WL0 to WL7 in the memory cells of erase block. Therefore, electrons stored in the charge trapping layers 43 of the memory cells of erase block are extracted, so that the erasing operation of the memory cells of erase block is performed.

Herein, if the four-levelled writing is directly performed after the erasing operation of the memory cell of each block, the memory cells having the threshold level distribution E and the threshold level distributions A to D mixedly exist in each block. At this time, the charge trapping layers 43 are continuously provided in the stacked direction of the word lines WL0 to WL3 (or the word lines WL4 to WL7), and in the structure, the charge trapping layer 43 of each memory cell connected to the word lines WL0 to WL3 (or the word lines WL4 to WL7) is insulator and share layer. Therefore, for example, in the case where the cell transistors MT0, MT2 to MT7 are maintained in the erased state so as to have the threshold level distribution E, and the cell transistor MT1 is subject to the writing so as to have the threshold level distribution A, the charge trapping layer 43 of the cell transistor MT1 is in the state where the electrons are trapped therein, and the charge trapping layers 43 of the cell transistors MT0, MT2 to MT7 are in the state where holes are trapped. Therefore, in some case, electric charges (electrons and holes) are recoupled between the adjacent cell transistors MT0 to MT2, so that data of the cell transistor MT1 may be lost.

For this reason, after the erasing operation is performed, before the two-levelled or four-levelled writing is performed, the initialization process is performed. As illustrated in FIG. 11B, in the initialization process, one-levelled writing operation is performed with respect to all the memory cells of each block, so that the threshold level distribution E of all the memory cells of each block after the erasing is set to the threshold level distribution A. In addition, in the example of FIG. 11B, the method of setting the threshold level distribution A after the initialization process to be positive is illustrated, any position where the threshold level distribution is higher than the threshold level distribution E can be used. However, in the writing operation, since the control may not be performed only in the direction where the threshold level distribution of the memory cell is increased, the voltage level of the threshold level distribution A after the initialization process is set to be lower than the voltage level of the two threshold level distributions A and B′ after writing operations.

In addition, in FIG. 11C, if LSB writing instruction is performed, the threshold level distribution A of the initial state is divided into two threshold level distributions A and B′, so that the writing of two-level state is performed. At this time, the upper limit of the threshold level distribution A can be set to be lower than a threshold level voltage Vb′, and the lower limit of the threshold level distribution B′ can be set to be higher than the threshold level voltage Vb′.

In addition, in FIG. 11D, if MSB writing instruction is performed, the threshold level distributions A and B′ of the two-level state are divided into four threshold level distributions A to D, so that the writing of four-level state is performed. At this time, the upper limit of the threshold level distribution A can be set to be lower than a threshold level voltage Vb, and the lower limit of the threshold level distribution B can be set to be higher than the threshold level voltage Vb. The upper limit of the threshold level distribution B can be set to be lower than threshold level voltage Vc, and the lower limit of the threshold level distribution C can be set to be higher than the threshold level voltage Vc. The upper limit of the threshold level distribution C can be set to be lower than threshold level voltage Vd, and the lower limit of the threshold level distribution D can be set to be higher than the threshold level voltage Vd.

Herein, the first and second flag data F1 and F2 are set according to the threshold level distributions illustrated in FIGS. 11A to 11D, and the first and second flag data F1 and F2 can be stored in the flag cells FC1 and FC2 illustrated in FIG. 5, respectively. Herein, in the case of the threshold level distribution illustrated in FIG. 11A, the first flag data F1 and the second flag data F2 can be set to “0”. In the case of the threshold level distribution illustrated in FIG. 11B, the first flag data F1 can be set to “1”, and the second flag data F2 can be set to “0”. In the case of the threshold level distribution illustrated in FIG. 11C, the first flag data F1 can be set to “1”, and the second flag data F2 can be set to “0”. In the case of the threshold level distribution illustrated in FIG. 11D, the first flag data F1 and the second flag data F2 can be set to “1”.

### Third Embodiment

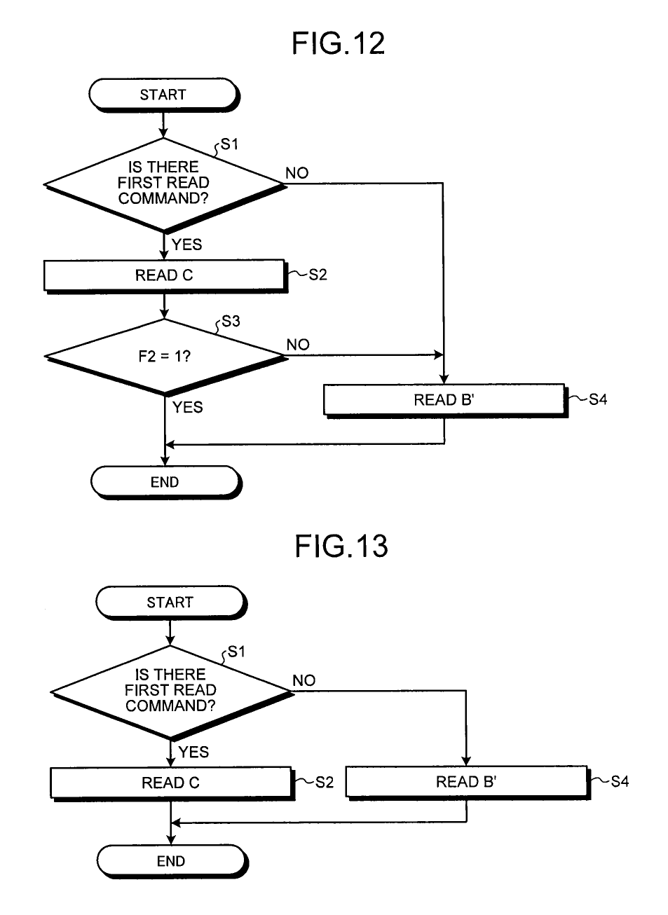

FIG. 12 is a flowchart illustrating an example of an LSB data reading method of a non-volatile semiconductor storage device according to a third embodiment.

In FIG. 12, in the case where the LSB is to be read from the memory cell array 11 illustrated in FIG. 5, the external control device issues the first read command or the second read command. In addition, the external control device can manage the first and second flag data F1 and F2 which are stored in the flag cells FC1 and FC2. Next, in the case where the second flag data F2 is “1”, the external control device can issue the first read command; in the case where the second flag data F2 is “0”, the external control device can issue the second read command.

Next, the read command issued from the external control device is transmitted through the buffer 22 to the command decoder 23, and it is determined whether the read command is a first read command or a second read command (Step S1).

Next, in the case where the read command issued from the external control device is the first read command, the reading of the selected cell of the memory cell array 11 is performed in the state where the reading level is set to the threshold level voltage Vc illustrated in FIG. 11D (Step S2).

Next, the second flag data F2 is read from the flag cell FC2 according to instruction from the sequence control circuit 18. Next, in the sequence control circuit 18, the level of the second flag data F2 is determined (Step S3), and in the case where the second flag data F2 is “1”, the reading process is ended.

On the other hand, in the sequence control circuit 18, in the case where the second flag data F2 is determined to be “0”, the reading of the selected cell of the memory cell array 11 is performed in the state where the reading level is set to the threshold level voltage Vb′ illustrated in FIG. 11C (Step S4).

In addition, in the case where the read command issued from the external control device is the second read command in Step S1, the reading of the selected cell of the memory cell array 11 is performed in the state where the reading level is set to the threshold level voltage Vb′ illustrated in FIG. 11C (Step S4).

Herein, the read command is properly used according to the level of the second flag data F2 managed by the external control device side, so that before the reading process of Step S2, the process of reading the second flag data F2 from the flag cell FC2 in the non-volatile semiconductor storage device side may not be performed. Accordingly, it is possible to reduce the reading times for the flag cell FC2.

FIG. 13 is a flowchart illustrating another example of an LSB data reading method of the non-volatile semiconductor storage device according to the third embodiment.

In FIG. 13, in order to reduce a processing time, the process of Step S3 illustrated in FIG. 12 is skipped, and the procedure may be transitioned from Step S2 directly to the end.

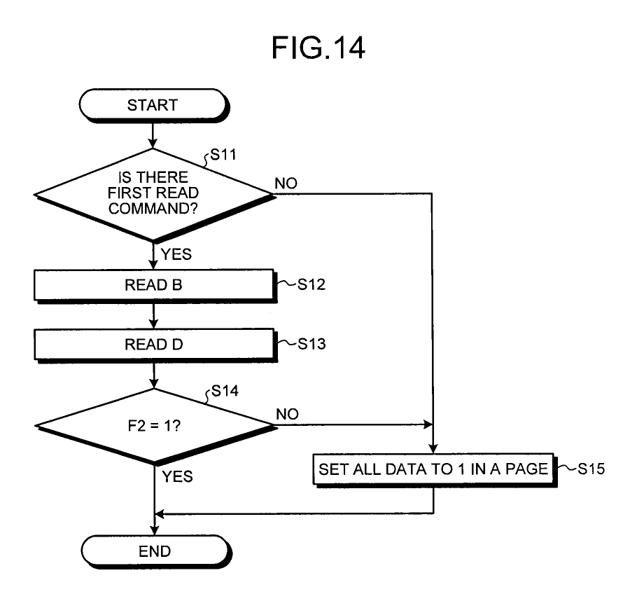

FIG. 14 is a flowchart illustrating an example of an MSB data reading method of the non-volatile semiconductor storage device according to the third embodiment.

In FIG. 14, in the case where the MSB is to be read from the memory cell array 11 illustrated in FIG. 5, the external control device issues the first read command or the second read command.

Next, the read command issued from the external control device is transmitted through the buffer 22 to the command decoder 23, and it is determined whether the read command is a first read command or a second read command (Step S11).

Next, in the case where the read command issued from the external control device is the first read command, the reading of the selected cell of the memory cell array 11 is performed in the state where the reading level is set to the threshold level voltage Vb illustrated in FIG. 11D (Step S12). In addition, the reading of the selected cell of the memory cell array 11 is performed in the state where the reading level is set to the threshold level voltage Vd illustrated in FIG. 11D (Step S13).

Next, the second flag data F2 is read from the flag cell FC2 according to instruction from the sequence control circuit 18. Next, the sequence control circuit 18, the level of the second flag data F2 is determined (Step S14), and in the case where the second flag data F2 is “1”, the reading process is ended.

On the other hand, in the sequence control circuit 18, in the case where the second flag data F2 is determined to be “0”, the all reading data in a page are set to “1” (Step S15).

In addition, in the case where the read command issued from the external control device is the second read command in Step S11, all of the data in a page are set to “1” (Step S15).

Herein, the read command is properly used according to the level of the second flag data F2 managed by the external control device side, so that before the reading process of Step S12, the process of reading the second flag data F2 from the flag cell FC2 in the non-volatile semiconductor storage device side may not be performed. Accordingly, it is possible to reduce the reading times for the flag cell FC2.

For example, although a time of 80 microseconds is taken for the reading operation using the first read command, the time for the reading operation using the second read command can be reduced down to about a half of the time, that is, 40 microseconds, so that the read performance of the non-volatile semiconductor storage device can be improved.

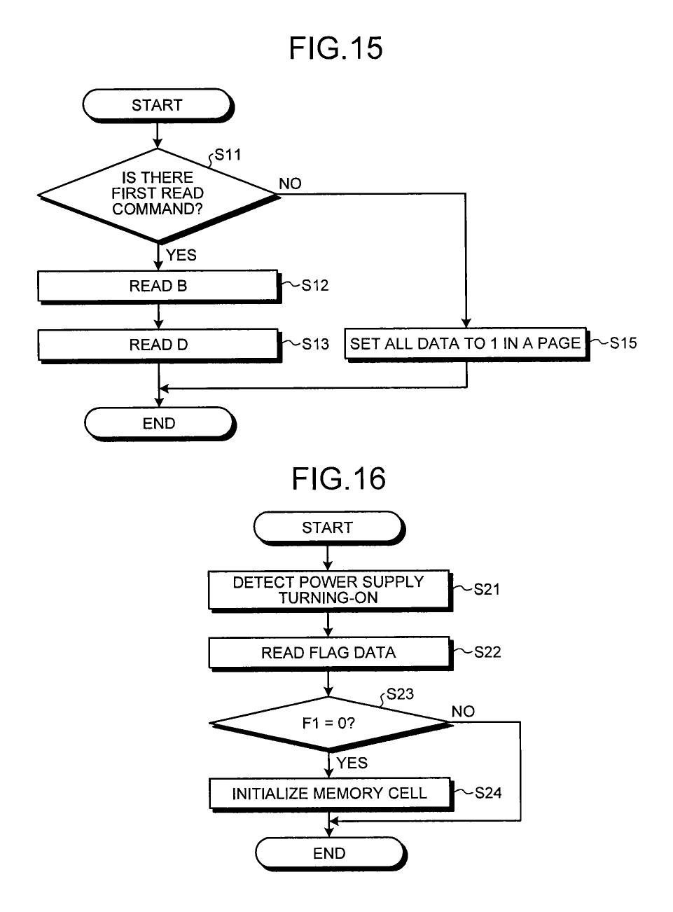

FIG. 15 is a flowchart illustrating another example of an MSB data reading method of the non-volatile semiconductor storage device according to the third embodiment.

In FIG. 15, in order to reduce a processing time, the process of Step S14 illustrated in FIG. 14 is skipped, and the procedure may be transitioned from Step S13 directly to the end.

### Fourth Embodiment

FIG. 16 is a flowchart illustrating an initialization process of a non-volatile semiconductor storage device according to a fourth embodiment.

In FIG. 16, if the sequence control circuit 18 illustrated in FIG. 5 is powered on through the power sensing circuit 20 (Step S21), the first flag data F1 is read from the flag cell FC1 (Step S22). Next, the level of the first flag data F1 is determined (Step S23), and in the case where the first flag data F1 is “0”, the initialization of the memory cell of the memory cell array 11 is performed (Step S24), so that the threshold level distribution E illustrated in FIG. 11A is transitioned into the threshold level distribution A illustrated in FIG. 11B.

Therefore, even in the case where the initialization process of transitioning the memory cell array 11 from the erased state to the initial state is stopped due to the power off or the like of the non-volatile semiconductor storage device illustrated in FIG. 5, the initialization process after the non-volatile semiconductor storage device is powered on can be performed and restarted only at the necessary page, so that the stability of the data storage can be improved.

In addition, in the embodiment illustrated in FIG. 16, although the method where the non-volatile semiconductor storage device site automatically performs the initialization process according to the level of the first flag data F1 is described, the initialization process may be performed based on instruction from an external control device side.

### Fifth Embodiment

In FIG. 5, the flag cells FC1 and FC2 are disposed at addresses exceeding the final address of each page. In this case, if the flag cells FC1 and FC2 are to be accessed from an external control device, the access prevention signal CE is activated in the final address determination circuit 27, so that the reading from the flag cells FC1 and FC2 is controlled not to be performed.

Herein, in order to allow the external control device to access the flag cells FC1 and FC2, third and fourth read commands can be mounted in the external control device. In addition, the third read command can cancel prevention of external access to the flag cell FC1. The fourth read command can cancel prevention of external access to the flag cell FC2.

Next, the third or fourth read command is issued from the external control device, and the read command is transmitted through the buffer 22 to the command decoder 23. Next, in the command decoder 23, an access prevention cancelling command CM is generated and transmitted to the access prevention cancelling circuit 28. Next, in the access prevention cancelling circuit 28, access prevention of the final address determination circuit 27 is cancelled with respect to the address exceeding the final address of each page, and thus the access prevention signal CE is inactivated, so that external access to the flag cells FC1 and FC2 is permitted.

Therefore, the first and second flag data F1 and F2 which are stored in the flag cells FC1 and FC2 can be read by the external control device side. Accordingly, even in the case where the first and second flag data F1 and F2 which are managed by the external control device side are lost, the first and second flag data F1 and F2 which are stored in the flag cells FC1 and FC2 can identified by the external control device side.

In addition, with respect to the reading of the first and second flag data F1 and F2, a method of directly outputting the levels may be used; and in the case where the first and second flag data F1 and F2 are configured with a plurality of bits, a method of indirectly outputting the final result through a plurality of circuits may be used. Alternatively, a method of adding the first and second flag data F1 and F2 to page data may be used. Concretely a method of outputting the first and second flag data F1 and F2 to address exceeding final column address may be used.

In addition, the memory system may be a single memory or, for example, may be an SD card including a single memory and a controller.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, a structure of 3 dimensional memory cell array may be a structure as shown in U.S. patent application Ser. No. 12/532,030 filed Sep. 28, 2009, which is incorporated by reference in their entirety.

What is claimed is:

1. A memory system including a non-volatile semiconductor storage device, comprising:
a memory cell configured to be capable of storing data of three or more levels;
a flag cell configured to be capable of storing a first data;
a first unit electrically connected to the flag cell, the first unit configured to generate the first data based on a threshold level of the memory cell; and
an second unit configured to generate a second data in order to allow access to the flag cell by external data.

2. The memory system according to claim 1, further comprising:
a row decoder electrically connected to the memory cell and the flag cell, the row decoder being configured to transfer a voltage for writing, reading, or erasing to word lines;
an amplifier circuit configured to determine data read out from the memory cell or the flag cell;
an address buffer configured to control the row decoder and the amplifier circuit;
a first circuit configured to control the amplifier circuit not to access a first area, the first area including the flag cell; and
wherein gates of the memory cell and the flag cell are connected to the word lines.

3. The memory system according to claim 2, further comprising:
an address buffer electrically connected to both the first circuit and the amplifier circuit;
wherein the first circuit does not provide an first signal to the address buffer during the reading or writing within the first area, the first signal being a signal prevent access to the first area, and
wherein the first circuit provides the first signal to the address buffer during the reading or writing within a second area, the second area being different from the first area, the second area including the memory cell.

4. The memory system according to claim 3, wherein the second unit temporarily cancels access limitation of the first circuit based on the external command.

5. A memory system including a non-volatile semiconductor storage device, comprising:
a memory cell configured to be capable of storing data of three or more levels;
a flag cell configured to be capable of storing a flag data, the flag data distinguishing whether the memory cell holding a only two level or not, and
wherein in the case where a command indicating a written state of only a first bit of the memory cell is externally issued based on the flag data during the reading of the first bit, the reading operation is performed at a reading level between a first and second threshold level distributions of the first bit.

6. A memory system including a non-volatile semiconductor storage device, comprising:
a memory cell configured to be capable of storing data of three or more levels; and
a flag cell configured to be capable of storing flag data distinguishing an erased state from an initial state of the memory cell, a threshold level of the initial state being higher than a threshold level of the erased state,
wherein the threshold level of the erased state is set to be negative, and
wherein the threshold level of the initial state is set to be positive.

7. The memory system according to claim 5, further comprising:
a first select transistor electrically connected to the memory cell,
a second select transistor electrically connected to the memory cell,
a word line electrically connected to gate of the memory cell; and
a bit line electrically connected to the first select transistor, and
wherein the flag cell shares the word line with the memory cell.

8. The memory system according to claim 5, further comprising:
a first unit configured to read the first data from the flag cell;
a second unit configured to store a first state when a page of the memory cell is two level state, the second unit configured to store a second state when a page of the memory cell is not two level state;
a third unit configured to issue a command for reading data from the memory cell based on the first data; and
a fourth unit configured to instruct reading and writing of the memory cell.

9. The memory system according to claim 8, wherein in the case where the flag data managed by the second unit indicates a written state of a lower bit and an upper bit, the command issuing unit issues a first command; and in the case where the flag data managed by the flag data managing unit indicates a written state of only the lower bit, the command issuing unit issues a second command.

10. The memory system including a non-volatile semiconductor storage device according to claim 9, wherein in LSB reading, in the case where the flag data is in a first state, the first read command for the LSB is issued from a controller, so that the reading of LSB corresponding to four levels from an address designated by the controller is performed.

11. The memory system according to claim 9, wherein in LSB reading, in the case where the flag data is in a second state, the second read command for the LSB is issued from a controller, so that the reading of LSB corresponding to two levels from an address designated by the controller is performed.

12. The memory system according to claim 9, wherein in MSB reading, in the case where the flag data is in a first state, the first read command for the MSB is issued from a controller, so that the reading of MSB corresponding to four levels from an address designated by the controller is performed.

13. The memory system according to claim 9, wherein in MSB reading, in the case where the flag data is in a second state, the second read command for the MSB is issued from a controller, so that the reading data of the entire page is set to the first state based on an address designated by the controller.

14. The memory system according to claim 5, wherein in the case where a command indicating the written state of only the first bit is externally issued based on the flag data during the reading of the second bit, the second bit is set to a first state.

15. The memory system according to claim 5, wherein the flag cell is disposed at addresses exceeding the final address of each page.

16. The memory system according to claim 6,
wherein the memory cell array includes:
a word line that performs row selection of the memory cell; and
a bit line that performs column selection of the memory cell, and
wherein the flag cell shares the word line with the memory cell and include a bit line dedicated to the memory cell.

17. The memory system according to claim 6, further comprising a controller which performs drive control for the memory cell,
wherein in the case where the memory cell array is determined to be in an erased state based on the flag data, the controller performs an initialization process of transitioning the memory cell array from the erased state to the initial state.

18. The memory system according to claim 17, wherein the controller includes:
a first unit configured to read the first data from the flag cell;
a second unit configured to manage the first data stored in the flag cell;
a third unit configured to issue a command for reading data from the memory cell based on the first data; and
a fourth unit configured to instruct reading and writing of the memory cell.

19. The memory system according to claim 18, wherein the flag cell is disposed at addresses exceeding the final address of each page.
